(19) United States
(12) Patent Application Publication
(10) Pub. No.: US 2004/0241968 A1
(43) Pub. Date: Dec. 2, 2004

(54) Production method and production device for semiconductor device

(76) Inventors: Shigemi Murakawa, Tokyo (JP); Shinichi Sato, Tokyo (JP); Toshio Nakanishi, Amagasaki-shi (JP)

Correspondence Address: CROWELL & MORING LLP, INTELLECTUAL PROPERTY GROUP, P.O. BOX 14300, WASHINGTON, DC, 20044-4300, US

(21) Appl. No.: 10/487,987

(22) PCT Filed: Aug. 29, 2002
(86) PCT No.: PCT/JP02/08736

(30) Foreign Application Priority Data
Aug. 29, 2001 (JP) 2001-260180

(51) Int. Cl. H01L 21/26; H01L 21/42; H01L 21/04

(52) U.S. Cl. 438/513; 438/542; 438/528; 438/510

(57) ABSTRACT

An impurity diffusion layer that structures a source region (15) and a drain electrode (16) of a pMOS 11 is formed extremely shallow, with a depth of approximately 50 nm. The extremely shallow impurity diffusion layer is formed by carrying out annealing process using RLSA plasma, after ion implantation processing at a low energy. In the annealing process, only silicon atoms near the surface of a silicon substrate (12) are selectively excited by the RLSA plasma, and impurity diffusion towards depth direction is suppressed.

### TECHNICAL FIELD

The present invention relates to a method and an apparatus for manufacturing a semiconductor device.

### BACKGROUND ART

In recent years, due to the request for achieving a high integration and a high density of an IC (Integrated Circuit), miniaturization of circuit elements is becoming an important task. Especially in a MOS (Metal-Oxide Semiconductor) transistor, when miniaturization of equal to or less than approximately 0.1 μm is carried out, a short channel effect becomes prominent, and problems such as decrease in a threshold voltage and deterioration of off-characteristics, etc., occur. To prevent an affect of the short channel effect in the MOS, it is effective to form impurity diffusion layers that constitutes (serves as) source and drain regions, shallow.

Forming of an impurity diffusion layer ordinarily comprises an ion implantation process of implanting ionized impurities into a surface region of a substrate, and annealing process of heating the surface region of the substrate into which the impurities are implanted to recover lattice defects caused by the ion implantation, and to place the implanted impurities at crystal lattice positions, thereby electrically activating the implanted impurities. Here, the forming of the shallow impurity diffusion layer is carried out by implanting the impurities with a low implantation energy, in the ion implantation process.

In the annealing process which is performed after the ion implantation process, a rapid thermal annealing, which is a method of irradiating light from a light source of a lamp, laser, etc., to the substrate into which the ions are implanted, thereby rapidly heating the substrate to a high temperature of approximately 1000° C., is used. Because only the surface of the substrate can be selectively heated, by the rapid thermal annealing (RTA), high-speed heating at a rate of approximately 100° C./second is possible, and processing at a short time of approximately 10 seconds is possible.

However, even in a case where annealing of a high temperature and of a short time is carried out using the RTA, diffusion of impurities can not be completely prevented This kind of diffusion of impurities is in a permissible range if the impurity implantation layer has a depth of a certain degree. However, in a case where the depth of the implantation layer is extremely shallow of approximately 50nm, the amount of impurities that diffuse deeper than the depth of the implantation layer, by heating, can not be ignored.

This is because even in a case where the RTA is used, a part of the substrate, which is at a depth deeper than an extremely shallow depth as above, is heated. Namely, by heating, silicon crystals at a deeper place than the implantation layer are excited, and the impurities transfer (diffuse) into the excited crystals. By the impurities diffusing in this way and being activated, substantial diffusion depth increases to a significant degree, and occurrence of short channel effect is not prevented, resulting to the deterioration in the reliability of the MOS.

As the above, it is necessary to selectively heat (excite) only the silicon crystals at the extremely shallow region of the substrate surface to form an extremely shallow impurity diffusion layer. However, conventionally, there is not an art like this.

### DISCLOSURE OF INVENTION

The present invention has been made in consideration of the above, and relates to a manufacturing method and a manufacturing apparatus of a highly reliable semiconductor device.

The present invention also relates to a manufacturing method and a manufacturing apparatus of a semiconductor device, which can reliably form an extremely shallow diffusion layer.

Further, the present invention relates to a manufacturing method and manufacturing apparatus of a semiconductor device, which selectively excites silicon crystals at the substrate surface.

To achieve the above objects, a manufacturing apparatus according to a first aspect of the present invention is characterized by comprising:

a plasma generating step of generating plasma by irradiating microwave of a predetermined frequency, from a plane antenna member comprising a plurality of slits, to a predetermined gas;

a diffusion layer forming step of forming an impurity diffusion layer by activating impurities doped into a substrate beforehand, by irradiating activated species in the generated plasma to the substrate.

In the above structure, it is preferable that the activated species are irradiated, while the substrate is heated at a predetermined temperature, in the diffusion layer forming step.

In the above structure, for example:

the impurities of the substrate is doped at a depth of 50 nm from the surface of the substrate; and

the diffusion layer forming step forms the impurity diffusion layer having a depth equal to or less than 50 nm from the surface of the substrate, by activating the impurities.

In the above structure, the gas is any one of Argon (Ar), Krypton (Kr), and Xenon (Xe), or the combination thereof.

In the above structure, the gas may further include Hydrogen (H₂).

In the above structure, the gas may further include Oxygen (O₂).

To achieve the above objects, a manufacturing apparatus of a semiconductor device according to a second aspect is characterized by comprising:

a chamber;

a gas supply unit which supplies predetermined gas to the chamber;

a plane antenna which receives microwave through a predetermined waveguide, and irradiates the microwave from a plurality of slits;

a substrate retainment unit that is placed opposing the plane antenna, and heats a substrate to be processed, wherein the substrate to be processed, which has impurities doped beforehand, in a situation that the substrate to be processed is applied a predetermined bias voltage is placed on the substrate retainment unit;

a reduced pressure exhaust unit which retains pressure in the chamber in a predetermined range; and

control means for turning said gas supplied to the chamber by the gas supply unit into plasma, by microwave from the plane antenna, and irradiating activated species in the plasma to the substrate to be processed, placed on the substrate retainment unit; and characterized in that

the control means forms an impurity diffusion layer by applying a predetermined bias voltage to the substrate to be processed by the substrate retainment unit, and thereby exciting the surface of the substrate to be processed by the activated species, and activating the impurities that are doped in the substrate to be processed.

### BRIEF DESCRIPTION OF THE DRAWINGS

FIG. 1 is a cross sectional view of a semiconductor device manufactured by a manufacturing apparatus of semiconductor device according to an embodiment of the present invention.

FIG. 2 is a diagram showing a structure of a manufacturing apparatus of a semiconductor device according to an embodiment of the present invention.

FIG. 3 is a diagram showing a structure of an annealing unit according to an embodiment of the present invention.

FIG. 4 is a diagram showing a structure of a plane antenna member (RLSA) according to an embodiment of the present invention.

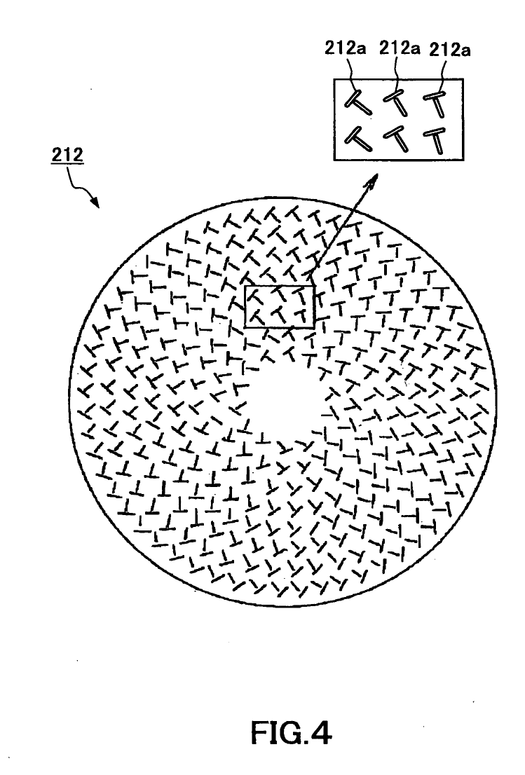

### BEST MODE FOR CARRYING OUT THE INVENTION

A manufacturing method and a manufacturing apparatus of a semiconductor device according to an embodiment of the present invention will be described with reference to the drawings.

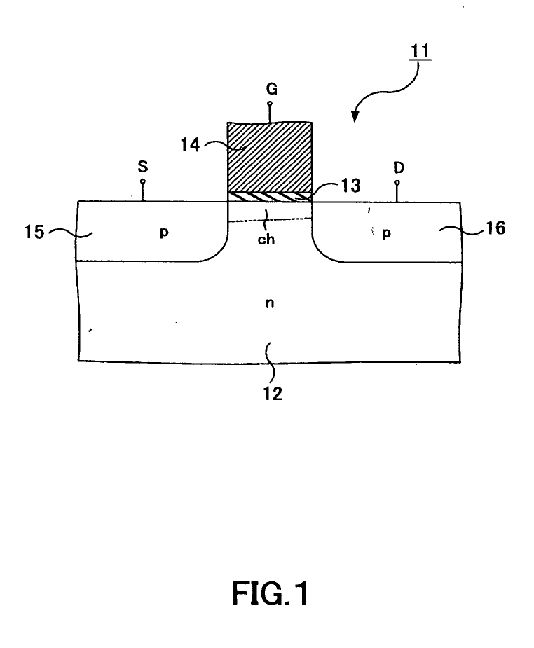

According to a manufacturing method of a semiconductor device of an embodiment of the present invention, for example, a p-channel MOSFET (Metal Oxide Semiconductor Field Effect Transistor) is manufactured. FIG. 1 shows the structure of a p-channel MOS (hereinafter referred to as pMOS) 11 manufactured using the manufacturing method of the semiconductor device of the present embodiment.

As shown in FIG. 1, the pMOS 11 comprises a silicon substrate 12, a gate insulating film 13, and a gate electrode 14.

The silicon substrate 12 is an n-type substrate formed by epitaxial growth, etc. The silicon substrate 12 may be an SOI (Silicon On Insulator) substrate.

The gate insulating film 13 is formed on the silicon substrate 12. The gate insulating film 13 comprises, for example, a silicon oxide film, a silicon nitride film, a silicon oxynitride film, and a stacked film of these films and a film having a high dielectric constant such as tantalum oxide, etc. The gate insulating film 13 has a thickness of for example, 2 to 5 nm (20Å to 50 Å).

The gate electrode 14 is stacked on the gate insulating film 13. The gate electrode 14 is made of polysilicon including impurities therein, and aluminum, etc. The gate electrode 14 has a thickness of for example 0.1 μm to 0.3 μm (1000 Å to 3000 Å).

At both sides of the gate insulating film 13, in the surface region of the silicon substrate 12, a source region 15 and a drain region 16 are formed. The source region 15 and the drain region 16 are p-type impurity diffusion regions, formed by introducing p-type impurities to the n-type silicon substrate 12.

The source region 15 and the drain region 16 are connected to a not-shown source electrode and a drain electrode, respectively. In a case where a predetermined voltage (gate voltage) is applied to the gate electrode 14, an inversion layer, i.e., a channel (ch) is formed in the surface region of the silicon substrate 12. In a case where a predetermined voltage is applied to the source electrode and drain electrode, a current flows between the source region 15 and the drain region 16 via the channel (ch).

Here, the impurity diffusion layers that serves as the source region 15 and the drain region 16, are each formed extremely shallow, at a depth of for example equal to or less than 2 nm to 50 nm (20 Å to 500 Å) towards the depth (thickness) direction of the substrate. The extremely shallow impurity diffusion layers are formed by performing ion implantation of p-type impurities (for example boron), ion implantation (impurity induction) by plasma doping, etc., and, then performing annealing processing. The annealing processing is performed by using microwave plasma using the latter described radial line slot antenna (RLSA).

Next, the manufacturing method of the semiconductor device (PMOS 11) according to an embodiment of the present invention will be described with reference to the drawings.

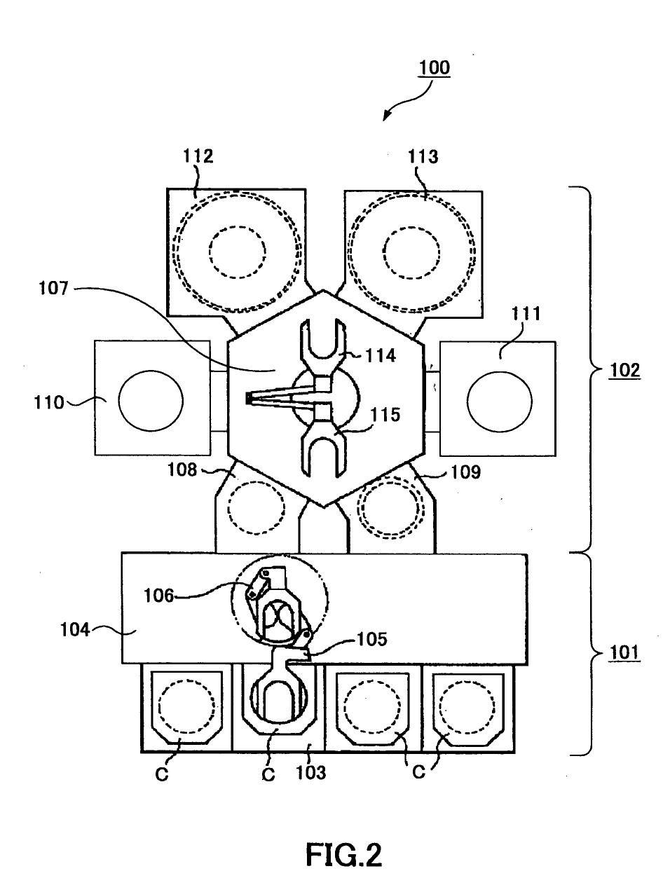

FIG. 2 shows the structure of a manufacturing apparatus 100 used for manufacturing the semiconductor device.

As shown in FIG. 2, the manufacturing apparatus 100 comprises a cassette station 101, and a processing station 102.

The cassette station 101 comprises a cassette stage 103, and a transferring room (chamber) 104. Each of cassettes C that can store a predetermined number of semiconductor wafers (hereinafter referred to as wafer W) are placed in the cassette stage 103. The cassettes C that store unprocessed wafers W are placed on the cassette stage 103, and the cassettes C that store processed wafers W are transferred out of the cassette stage 103.

A pair of loader arms 105, 106 is placed in the transferring room 104. The loader arms 105, 106 transfer in wafers W stored in the cassettes C to the processing station 102, and transfer out processed wafers W from the processing station 102, and store the processed wafers W in the cassettes C. The interior of the transferring room 104 is kept clean by the down flow of clean air.

The processing station 102 comprises a vacuum platform 107, two load lock units 108, 109, two doping units 110, 111, and two annealing units 112, 113.

Each unit is arranged around the approximately hexagon vacuum platform (107) and can be interconnected or secluded with the approximately hexagon vacuum platform (107) via gate valves. Namely, the processing station 102 constitutes a cluster type system. The vacuum platform 107 comprises an exhaust mechanism, and its interior can be decompressed to a predetermined vacuum situation. Each unit separated by the gate valve, respectively comprises an exhaust mechanism, and an atmosphere independent from the vacuum platform 107 can be formed therein.

In the center of the vacuum platform 107, a pair of transferring arms 114, 115 which transfer the wafers W between the units are provided.

The load lock units 108, 109 can be interconnected to or secluded from the transferring room 104 of the cassette station 101. The load lock units 108, 109 serve as ports of the processing station 102 for transferring in wafers and transferring out wafers. The loader arms 105, 106 transfer in the wafers W stored in the cassette C, which is on the cassette stage 103, to the interior of the load lock units 108, 109. The loader arms 105, 106 transfer out the processed wafers W from the load lock units 108, 109, and store them in the cassette C.

The doping units 110, 111 comprise a general low energy ion implantation apparatus, and a general plasma doping apparatus, etc. The doping units 110, 111 introduce p-type impurities to the silicon substrates 12 (wafers W) selectively, thereby impurity implanted layers are formed.

Impurity introduction is carried out self-aligningly for example, by using the gate electrode 14 as a mask. Impurity is introduced at a dose of for example, 1×10¹³ to 5×10¹⁵cm⁻² and diffusion depth of for example 2 nm to 50 nm (20 Å to 500 Å). Boron (B), and indium (In), etc. can be used as the p-type impurities.

The annealing units 112, 113 are radial line slot antenna (RLSA) type plasma processing apparatuses. The annealing units 112, 113 generate plasma of processing gas using microwave energy, and anneal the surfaces of silicon substrates 12 after doping, by the plasma.

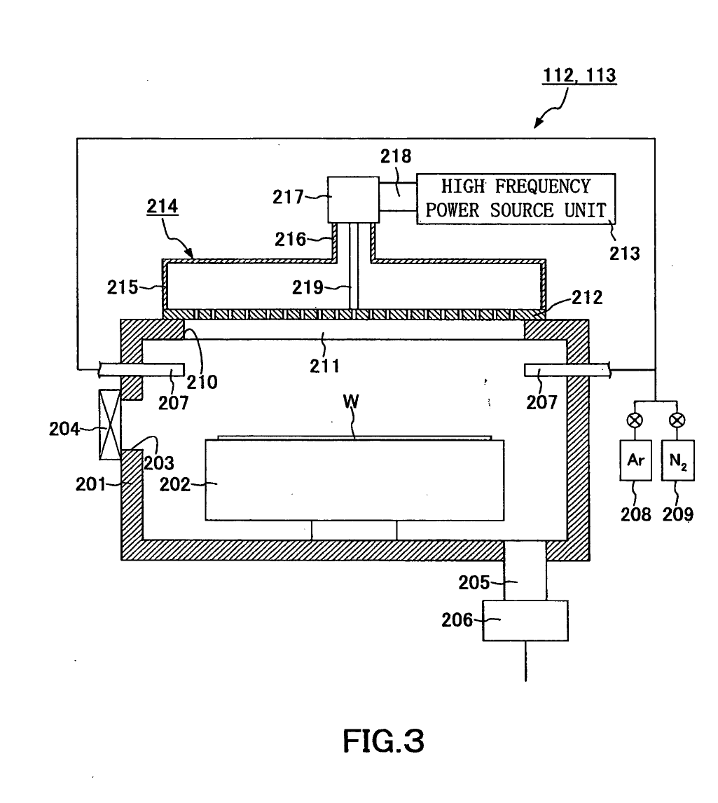

FIG. 3 shows the cross-sectional structure of the annealing units 112, 113. As shown in FIG. 3, the annealing units 112, 113 comprise an approximately cylindrical chamber 201. The chamber 201 is formed of aluminum, etc.

In the center of the interior of the chamber 201, a placing base (susceptor) 202 for the wafer W which is to be processed, is placed. A not shown temperature controller is embedded in the placing base 202, and the wafer W is heated to a predetermined temperature, for example, room temperature to 600° C., by the temperature controller.

The placing base 202 has a circuit for applying a predetermined voltage. A bias voltage (for example, −50V to 0V, preferably, −20V to 0V), for accelerating ions in the plasma, is applied to the wafer W by the circuit.

On the side wall of the chamber 201, a transferring gate 203 is provided at the same height as the top surface of the placing base 202. The transferring gate 203 is connected to the vacuum platform 107 via a gate valve 204. When the gate valve 204 is open, transferring in and out of the wafer W is carried out via the transferring gate 203.

At the bottom part of the chamber 201, one end of an exhaust tube 205 is connected, and the other end is connected to an exhaust apparatus 206, such as a vacuum pump, etc. By the exhaust apparatus 206, etc., the interior of the chamber 201 at the time of processing is set at 40 Pa to 0.13 kPa (30 mTorr to 1 Torr).

On the upper portions of sidewall of the chamber 201, gas supply tubes 207 are provided. The gas supply tubes 207 are connected to Argon (Ar) gas source 208 and Nitrogen (N₂) gas source 209. The gas supply tubes 207 are placed along the circumferential direction of the side wall of the chamber 201, for example, evenly in 16 places. By being placed this way, gas supplied from the gas supply tubes 207 are supplied evenly to the upside of the wafer W on the placing base 202.

An opening 210 is provided on the upper part of the chamber 201. Inside of the opening 210, a window 211 is provided. The window 211 comprises a film and a sheet of transmission material, which is glass comprising quartz, SiO₂ glass, inorganic material such as Si₃N₄, NaCl, KCl, LiF, CaF₂, BaF₂, Al₂O₃, AlN, and MgO, and organic material such as polyethylene, polyester, polycarbonate, celluloseacetate, polypropylene, polyvinylchloride, polyvinylidenechloride, polystyrene, polyamide, and polyimide.

For example, a radial line slot antenna (hereinafter referred to as RLSA) 212 is provided on the window 211. A waveguide 214 connected to a high frequency power source unit 213 is provided on the RLSA 212. The waveguide 214 comprises a flat circular waveguide tube 215, which the bottom end thereof is connected to the RLSA 212, a cylindrical waveguide tube 216, which one end thereof is connected to the upper surface of the circular waveguide tube 215, a coaxial waveguide converter 217, which is connected to the upper surface of the cylindrical waveguide tube 216, and a rectangular waveguide tube 218, which one end thereof is connected perpendicular to the side surface of the coaxial waveguide converter 217, and the other end thereof is connected to the high frequency power source unit 213. The RLSA 212 and the waveguide 214 comprise copper plates.

In the interior of the cylindrical waveguide tube 216, a coaxial waveguide tube 219 is placed. The coaxial waveguide tube 219 is made of axial material, which comprises conductive material, and one end thereof is connected to approximately the center of the top surface of the RLSA 212, and the other end is connected to the top surface of the cylindrical waveguide tube 216, coaxially.

FIG. 5 shows a plane view of the RLSA 212. As shown in FIG. 5, the RLSA 212 comprises on the surface, a plurality of slots 212a, which are provided concentrically. Each slot 212a is an approximately rectangle penetrated trench, and is arranged so that the adjacent slots 212a intersect with each other, to form an approximate alphabet T. The length and arrangement interval of the slots 212a are determined according to the wavelength of the high frequency wave generated by the high frequency power source unit 213.

The high frequency power source unit 213 generates a microwave of for example 2.45 GHz, at an electric power of for example 500 W to 5 kW. The microwave generated from the high frequency power source unit 213 is transmitted through the rectangular waveguide tube 218 in a rectangular mode. Further, the microwave is converted from the rectangular mode to a circular mode by the coaxial waveguide converter 217, and transferred to the cylindrical waveguide tube 216 in the circular mode. Further, the microwave is transferred in a state, extended in the circular waveguide tube 215, and is emitted from the slots 212a of the RLSA 212. The emitted microwave is supplied to the chamber 201 through the window 211.

The interior of the chamber 201 is set at a predetermined vacuum pressure, and mixed gas of Ar and N₂ is supplied to the interior of the chamber 201 from the gas supply tubes 207, at for example, Ar/N₂₌2000 (sccm)/200 (sccm). Here, the flow ratio may be Ar/N₂₌2000/20 or 1000/100.

By the microwave passing through the window 211, high frequency energy is transmitted to the mixed gas in the chamber 201, and high frequency plasma is generated. At this time, because microwave is emitted from the many slots 212a of the RLSA 212, high density plasma is generated. Here, activated species in the plasma, formed by using the RLSA 212 has an electron temperature of 0.7 to 2 eV. By this way, according to the. RLSA 212, plasma activated species with a relatively placid activation is generated.

By exposure to the generated high density plasma, annealing of the surface of the wafer W is carried out. Namely, activated species in the generated plasma, especially Ar ion, contacts and collides with silicon atoms on the surface of the wafer W, thereby provides energy to the silicon atoms on the substrate surface. The provided energy is transmitted from silicon atoms on the surface of the silicon substrate to silicon atoms at a deeper position. By this energy transmission, silicon atoms (crystal) at a predetermined depth excite.

Excitation of silicon crystal occurs in the same way, as in the impurity implant layer. By excitation, re-alignment (recrystallization) of out of order silicon crystal caused by implanting (doping), occurs. By this, lattice defect of the implanted layer decreases or disappears.

At this time, at the same time as the re-alignment of the crystal lattice, the impurities (B, etc., ) introduced by doping, which were not placed at a predetermined crystal lattice position, settle at the crystal lattice position, and are activated as dopant. By this, impurity diffusion layers (source region 15 and drain region 16) that have stable requested electric characteristics, can be obtained.

Here, as described above, plasma activated species generated by using RLSA has a relatively low energy. Therefore, damage to the surface of the silicon substrate 12 can be prevented. Energy provided to the silicon crystal by the activated species is consumed by re-alignment, etc., of silicon crystal in the transmitting process, and is not transmitted to silicon atoms at a depth equal to or deeper than the predetermined depth from the surface.

From this, by adequately adjusting the generation condition of plasma, activated species having energy approximately equal to energy by which silicon atoms at the depth of the implanted layer (approximately 50 nm) are selectively excited and silicon atoms at a depth deeper thereof are not excited, are generated. Thereby, diffusion of impurities at a depth equal to or deeper than the implanted layer can be suppressed.

Manufacturing method of the semiconductor device according to the present embodiment, will be described with reference to FIG. 2;

First, a cassette C that stores a predetermined number of wafers W is placed on the cassette stage 103. The wafers W are formed by the gate insulating layer 13 and the gate electrode 14 being stacked on the silicon substrate 12. The loader arms 105, 106 transfer out wafers W from the cassette C, and transfer them into the load lock units 108, 109.

After the wafers W are transferred in, the interior of the load lock units 108, 109 are made airtight, and the pressure in the interior of the load lock units 108, 109 are made close to the pressure of the interior of the vacuum platform 107. Thereafter, the load lock units 108 and 109 are opened towards the vacuum platform side. Then, the transferring arms 114, 115 transfer wafers W out of the load lock units 108 and 109.

The transferring arms 114 and 115 transfer in wafers W to the doping units 110, 111. After the wafers W are transferred in, the gate valves are closed, and the interior of the doping units 110, 111 are set to a predetermined pressure. Then, impurity introduction is carried out self-aligningly, by using the gate electrode 14 as a mask, towards wafers W. By this, the source region 15 and the drain region 16 are formed near the gate electrode 14. After doping, the interior of the doping units 110, 111 are set to the original pressure, and the gate valves are opened. The transferring arms 114, 115 transfer out the processed wafers W.

Then, the wafers W are transferred into the annealing units 112, 113. After the wafers W are transferred in, the gate valves are closed, and the interior of the annealing units 112, 113 are set at a predetermined pressure. Annealing processing by RLSA plasma is carried out to the wafers W in the annealing units 112, 113. By this, diffusion of impurities can be suppressed, and the surface region of the wafers W stabilizes, retaining the depth of the impurity diffusion layer extremely shallow. After the annealing processing is finished, the interior of the annealing units 112, 113 are set to the original pressure, and the gate valves are opened. The transferring arms 114, 115 transfer out the processed wafers W.

The wafers W after the annealing processing, are transferred into the load lock units 108, 109. Thereafter, the wafers W are stored in the cassette C, in accordance with a process that is reverse the process of transferring in the wafers W to the load lock units 108, 109. The cassette C that stores a predetermined number of processed wafers W is transferred out of the semiconductor manufacturing apparatus 100. Forming of insulating layer and forming of gate and drain electrodes are carried out towards the processed wafers W. In the above way, the manufacturing processing of the pMOS 11 is completed.

As described above, in the embodiment of the present invention, annealing of the impurity diffusion layer is carried out by contacting plasma activated species generated by using RLSA 212 to the surface of the substrate 12. Energy of the generated activated species is energy that selectively excites only silicon atoms which are at a depth, barely deeper than the impurity diffusion layer without providing damage to the surface of the silicon substrate 12.

As above, annealing of the impurity diffusion layer using RLSA plasma can selectively excite silicon crystal at a predetermined depth from the substrate surface, and suppresses diffusion of impurities. Therefore, even in impurity diffusion layers that are extremely shallow, the depth is retained shallow, and a highly reliable pMOS 11, with short channel effect prevented, can be obtained.

The present invention is not limited to the above descriptions of the embodiment, and modifications and changes, etc., are arbitrary.

In the above embodiment, pMOS is described as an example. However, the pMOS may be substituted to an n-channel MOS. In this case, by using n-type impurities, such as arsenic, phosphorus, or antimony, etc., as dopant, an extremely shallow n-type impurity diffusion layer can be formed. Or, the pMOS may be substituted to MIS (Metal Insulator Semiconductor) FET, or CMOS (Complementary MOS) FET, etc.

In the above embodiment, the semiconductor manufacturing apparatus 100 comprises two doping units, 110, 111, and two plasma annealing units 112, .113. However, the number and arrangement of units that structure the semiconductor manufacturing apparatus 100 is arbitrary.

In the above embodiment, mixed gas of Ar and N₂ is used in the annealing processing carried out in the annealing units 112, 113. However, krypton (Kr), or xenon (Xe), etc., may be used independently or mixed.

Additionally, O₂ may be used instead of N₂. Or, H₂, or O₂, etc., may be added. Especially, if H₂ is added, H radical generated from H₂ bonds with the dangling bond of Si, and stabilizes the formed silicon oxide film, thereby the film quality can be improved.

According to the present invention, a manufacturing method and manufacturing apparatus of a highly reliable semiconductor device can be provided.

### INDUSTRIAL APPLICABILITY

The present invention is useful for manufacturing semiconductor devices. The patent application is based on Japanese Patent Application No. 2001-260180 filed with the Japan Patent Office on Aug. 29, 2001 and includes specification, claims, drawings, and abstract, the complete disclosure of which is hereby incorporated by reference.

1. A manufacturing method of a semiconductor device characterized by comprising:
a plasma generating step of generating plasma by irradiating microwave of a predetermined frequency, from a plane antenna member (212) comprising a plurality of slits, to a predetermined gas;
a diffusion layer forming step of forming an impurity diffusion layer by activating impurities doped into a substrate (W) beforehand, by irradiating activated species in the generated plasma to the substrate (W).

2. The manufacturing method of the semiconductor device according to claim 1, characterized in that the diffusion layer forming step irradiates said activated species, while heating the substrate (W) to a predetermined temperature.

3. The manufacturing method of the semiconductor device according to claim 1, characterized in that:
the impurities of said substrate (W) is doped at a depth of 50 nm from the surface of said substrate (W); and
said diffusion layer forming step forms the impurity diffusion layer having a depth equal to or less than 50 nm from the surface of said substrate (W), by activating said impurities.

4. The manufacturing method of the semiconductor device according to claim 2, characterized in that:
the impurities of said substrate (W) is doped at a depth of 50 nm from the surface of said substrate (W); and
said diffusion layer forming step forms an impurity diffusion layer having a depth equal to or less than 50 nm from the surface of said substrate (W), by activating said impurities.

5. The manufacturing method according to claim 1, characterized in that said gas is any one of Argon (Ar), Krypton (Kr), and Xenon (Xe), or the combination thereof.

6. The manufacturing method according to claim 2, characterized in that said gas is any one of Argon (Ar), Krypton (Kr), and Xenon (Xe), or the combination thereof.

7. The manufacturing method according to claim 3, characterized in that said gas is any one of Argon (Ar), Krypton (Kr), and Xenon (Xe), or the combination thereof.

8. The manufacturing method according to claim 4, characterized in that said gas is any one of Argon (Ar), Krypton (Kr), and Xenon (Xe), or the combination thereof.

9. The manufacturing method according to claim 5, characterized in that said gas further includes Hydrogen (H₂).

10. The manufacturing method according to claim 6, characterized in that said gas further includes Hydrogen (H₂).

11. The manufacturing method according to claim 7, characterized in that said gas further includes Hydrogen (H₂).

12. The manufacturing method according to claim 8, characterized in that said gas further includes Hydrogen (H₂).

13. The manufacturing method according to claim 5, characterized in that said gas further includes Oxygen (O₂).

14. The manufacturing method according to claim 6, characterized in that said gas further includes Oxygen (O₂).

15. The manufacturing method according to claim 7, characterized in that said gas further includes Oxygen (O₂).

16. The manufacturing method according to claim 8, characterized in that said gas further includes Oxygen (O₂).

17. A manufacturing apparatus (112, 113) of a semiconductor device characterized by comprising:
a chamber (201);
a gas supply unit (207) which supplies predetermined gas to the chamber (201);
a plane antenna (212) which receives microwave through a predetermined waveguide (214), and irradiates the microwave from a plurality of slits (212a);
a substrate retainment unit (202) that is placed opposing the plane antenna (212) and heats a substrate (W) to be processed, wherein the substrate (W) to be processed, which has impurities doped beforehand, in a situation that the substrate (W) to be processed is applied a predetermined bias voltage, is placed on the substrate retainment unit (202);
a reduced pressure exhaust unit (206) which retains pressure in the chamber (201) in a predetermined range; and
control means for turning said gas supplied to the chamber (201) by said gas supply unit (27) into plasma, by microwave from the plane antenna (212), and irradiating activated species in the plasma to the substrate (W) to be processed, placed on the substrate retainment unit (202); and characterized in that
said control means forms an impurity diffusion layer by applying a predetermined bias voltage to the substrate (W) to be processed by the substrate retainment unit (202), and thereby exciting the surface of the substrate (W) to be processed by the activated species, and activating the impurities that are doped in the substrate (W) to be processed.
